(19) United States
(12) Patent Application Publication
(10) Pub. No.: US 2011/0096068 A1
(43) Pub. Date: Apr. 28, 2011

(54) LEVEL SHIFTER

(76) Inventors: Yoon-kyung Choi, Yongin-si (KR); Hyoung-rae Kim, Hwaseong-si (KR); Min-soo Cho, Yongin-si (KR)

(21) Appl. No.: 12/910,035

(22) Filed: Oct. 22, 2010

(30) Foreign Application Priority Data
Oct. 22, 2009 (KR) 10-2009-0100767

(51) Int. Cl. G09G 5/00; H03L 5/00

(52) U.S. Cl. 345/213; 327/333

(57) ABSTRACT

A level shifter including a voltage selection unit and at least one voltage level conversion unit. The voltage selection unit may be configured to apply a first voltage to a power supply node during a first time interval and apply a second voltage to the power supply node during a second time interval, in response to a control signal. The voltage level conversion unit may be connected to the power supply node and may be configured to convert a voltage level of an input signal to another voltage level based upon a voltage level at the power supply node and a third voltage.

### CROSS-REFERENCE TO RELATED APPLICATION

This application claims priority to and the benefit of Korean Patent Application No. 10-2009-0100767, filed on Oct. 22, 2009, in the Korean Intellectual Property Office, the entire content of which is incorporated by reference herein.

### BACKGROUND

1. Technical Field

The inventive concept relates to a level shifter, and more particularly, to a level shifter capable of reducing the size of a semiconductor device.

2. Discussion of the Related Art

A semiconductor device may include a level shifter configured to change the voltage level of an applied voltage to another voltage level. A level shifter may be used when a circuit requires a voltage level different from the voltage level of the applied voltage to operate properly. For example, a display device may include a level shifter configured to change a low voltage level of an applied voltage to a high voltage level.

### SUMMARY

According to an exemplary embodiment of the inventive concept, a level shifter includes a voltage selection unit and at least one voltage level conversion unit. The voltage selection unit may be configured to apply a first voltage to a power supply node during a first time interval and apply a second voltage to the power supply node during a second time interval, in response to a control signal. The voltage level conversion unit may be connected to the power supply node and configured to convert a voltage level of an input signal to another voltage level based upon a voltage level at the power supply node and a third voltage.

The third voltage may be a ground voltage. The first voltage may have a voltage level greater than the third voltage. The second voltage may have a voltage level greater than the first voltage.

The voltage selection unit may include a first switching unit and a second switching unit. The first switching unit may be configured to connect a first voltage source for providing the first voltage to the power supply node during the first time interval and to disconnect the first voltage source from the power supply node during the second time interval, in response to the control signal. The second switching unit may be configured to connect a second voltage source for providing the second voltage to the power supply node during the second time interval and to disconnect the second voltage source from the power supply node during the first time interval, in response to the control signal.

The first switching unit may include a p-channel metal-oxide-semiconductor (PMOS) field-effect transistor. The second switching unit may include an n-channel metal-oxide-semiconductor (NMOS) field-effect transistor.

The voltage level conversion unit may include a first voltage level control unit and a second voltage level control unit. The first voltage level control unit may be configured to apply one of a voltage of the power supply node or the third voltage to a second node, based upon the input signal and a voltage level at a first node. The second voltage level control unit may be configured to apply one of the voltage of the power supply node or the third voltage to the first node, based upon an inverted input signal obtained by inverting the input signal, and a voltage level at the second node. A first output signal of the voltage level conversion unit may be output through the first node, and a second output signal of the voltage level conversion unit may be output through the second node.

The first voltage level control unit may be configured to connect the second node to the power supply node while the input signal is in a first logic state, and to connect the second node to the third voltage while the input signal is in a second logic state.

The first voltage level control unit may include a first transistor and a second transistor. The first transistor may include a gate connected to the first node, a first terminal connected to the power supply node, and a second terminal connected to the second node. The second transistor may include a gate to which the input signal is applied, a first terminal connected to the second node, and a second terminal to which the third voltage is applied.

The second voltage level control unit may be configured to connect the first node to the power supply node while the inverted input signal is in a first logic state, and to connect the first node to the third voltage while the input signal is in a second logic state.

The second voltage level control unit may include a first transistor and a second transistor. The first transistor may include a gate connected to the second node, a first terminal connected to the power supply node, and a second terminal connected to the first node. The second transistor may include a gate to which the inverted input signal is applied, a first terminal connected to the first node, and a second terminal to which the third voltage is applied.

The input signal may be changed from a first logic state to a second logic state or from the second logic state to the first logic state during the first time interval.

According to an exemplary embodiment of the inventive concept, a display device includes a panel which includes a plurality of pixel regions, a source driver including a level shifter and configured to drive source lines of the panel, and a controller configured to control the source driver. The level shifter may include a voltage selection unit and at least one voltage level conversion unit. The voltage selection unit may be configured to apply a first voltage to a power supply node during a first time interval and apply a second voltage to the power supply node during a second time interval, in response to a control signal. The voltage level conversion unit may be connected to the power supply node and configured to convert a voltage level of an input signal to another voltage level based upon a voltage level at the power supply node and a third voltage.

The third voltage may be a ground voltage. The first voltage may have a voltage level greater than the third voltage. The second voltage may have a voltage level greater than the first voltage.

According to an exemplary embodiment of the inventive concept, a system apparatus includes a level shifter configured to shift a voltage level of an applied voltage and output a shifted voltage, and a memory device configured to receive the shifted voltage from the level shifter. The level shifter may include a voltage selection unit and at least one voltage level conversion unit. The voltage selection unit may be configured to apply a first voltage to a power supply node during a first time interval and apply a second voltage to the power supply node during a second time interval, in response to a control signal. The voltage level conversion unit may be connected to the power supply node and may be configured to convert a voltage level of an input signal to another voltage level based upon a voltage level at the power supply node and a third voltage.

The third voltage may be a ground voltage. The first voltage may have a voltage level greater than the third voltage. The second voltage may have a voltage level greater than the first voltage.

### BRIEF DESCRIPTION OF THE DRAWINGS

Exemplary embodiments of the inventive concept will be more clearly understood from the following detailed description taken in conjunction with the accompanying drawings in which:

FIG. 1 is a block diagram of a level shifter according to an exemplary embodiment of the inventive concept;

FIG. 2 is a block diagram of a level shifter according to an exemplary embodiment of the inventive concept;

FIG. 3A is a circuit diagram of an exemplary embodiment of a voltage selection unit included in the level shifters illustrated in FIGS. 1 and 2;

FIG. 3B is a circuit diagram of an exemplary embodiment of a voltage selection unit included in the level shifters illustrated in FIGS. 1 and 2;

FIG. 3C is a circuit diagram of an exemplary embodiment of a voltage selection unit included in the level shifters illustrated in FIGS. 1 and 2;

FIG. 4 is a circuit diagram of a voltage level conversion unit included in the level shifter illustrated in FIG. 1, according to an exemplary embodiment of the inventive concept;

FIG. 5 is a waveform diagram showing signals input to and output from the voltage level conversion unit illustrated in FIG. 4, as well as signals at each node of the voltage level conversion unit;

FIG. 6 is a block diagram of a display device according to an exemplary embodiment of the inventive concept;

FIG. 7 is a block diagram of a source driver included in the display device illustrated in FIG. 6, according to an exemplary embodiment of the inventive concept;

FIG. 8 is a block diagram of a computing system apparatus according to an exemplary embodiment of the inventive concept; and

FIG. 9 is a block diagram of a memory card according to an exemplary embodiment of the inventive concept.

### DETAILED DESCRIPTION OF THE EMBODIMENTS

Exemplary embodiments of the inventive concept will be described more fully hereinafter with reference to the accompanying drawings.

The inventive concept may, however, be embodied in many different forms and should not be construed as limited to the exemplary embodiments set forth herein. Like reference numerals refer to like elements throughout the accompanying drawings.

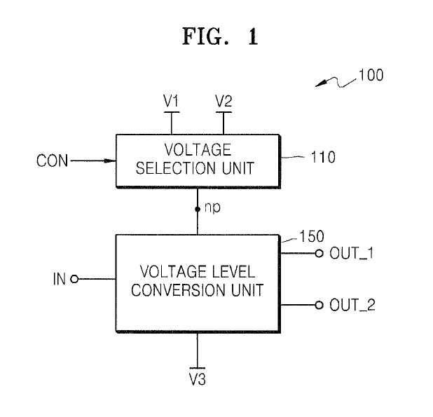

FIG. 1 is a block diagram of a level shifter 100 according to an exemplary embodiment of the inventive concept.

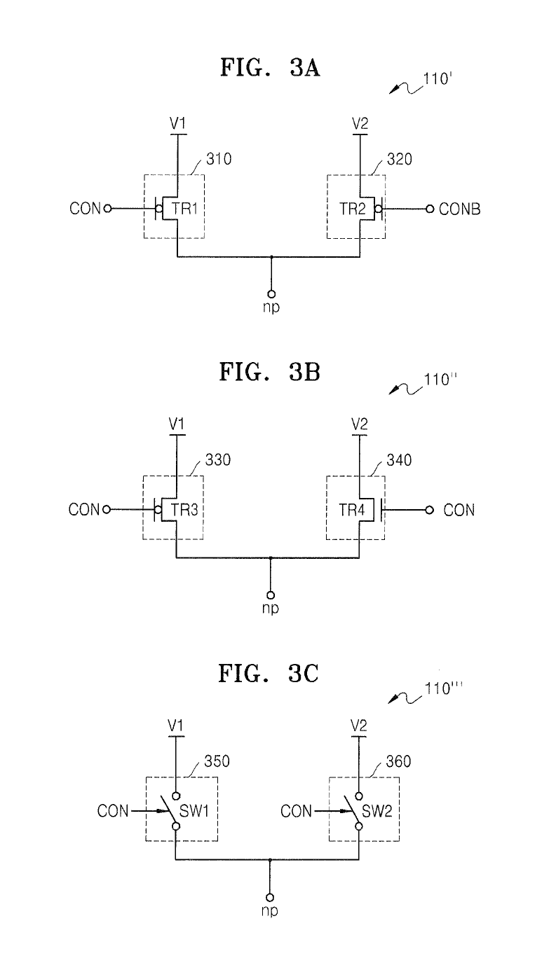

Referring to FIG. 1, the level shifter 100 may include a voltage selection unit 110 and a voltage level conversion unit 150. The voltage selection unit 110 may select a first voltage V1 or a second voltage V2 in response to a control signal CON and apply the selected first or second voltage V1 or V2 to a power supply node np. For example, in response to the control signal CON, the voltage selection unit 110 may apply the first voltage V1 to the power supply node np during a first time interval and apply the second voltage V2 to the power supply node np during a second time interval. Exemplary embodiments of the voltage selection unit 110 are described in more detail with reference to FIGS. 3A through 3C.

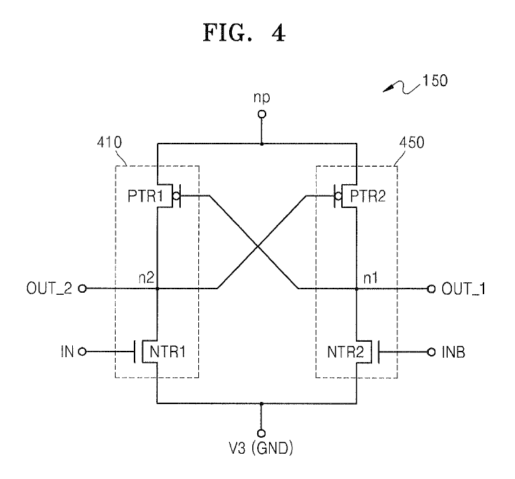

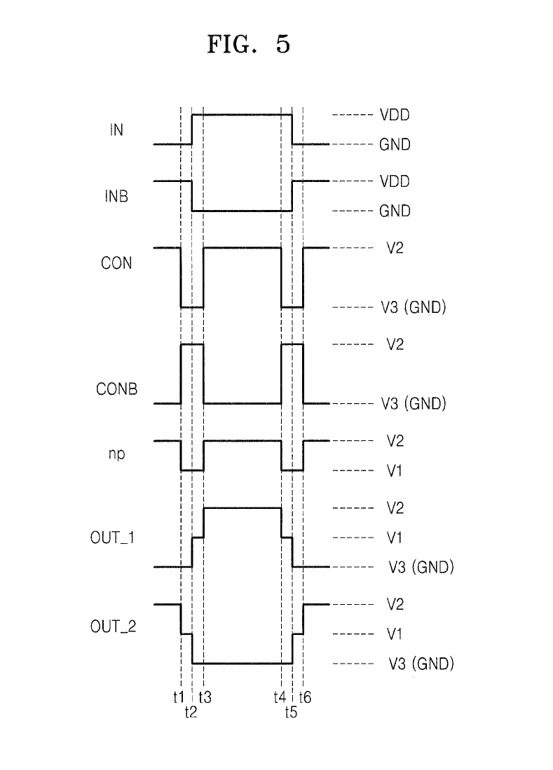

The voltage level conversion unit 150 may be connected to the power supply node np and may convert the voltage level of an input signal IN to another voltage level based upon a voltage of the power supply node np and a third voltage V3. The voltage level conversion unit 150 outputs a first output signal OUT_1 and a second output signal OUT_2. For example, the voltage level conversion unit 150 may convert the voltage level of the input signal IN to a first voltage level during the first time interval based upon the first voltage V1 and the third voltage V3, and may convert the voltage level of the input signal IN to a second voltage level during the second time interval based upon the second voltage V2 and the third voltage V3. Exemplary embodiments of the voltage level conversion unit 150 are described in more detail with reference to FIGS. 4 and 5.

The third voltage V3 may be, for example, a ground voltage, the first voltage V1 may be a voltage higher than the third voltage V3, and the second voltage V2 may be a voltage higher than the first voltage V1.

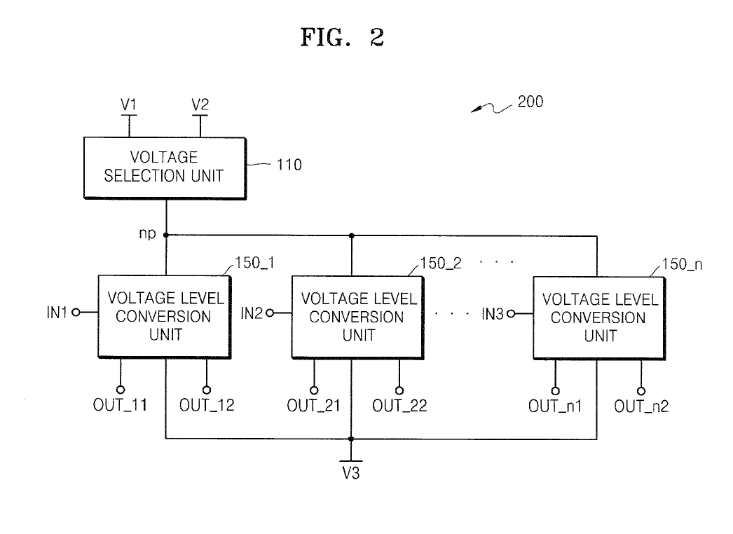

FIG. 2 is a block diagram of a level shifter 200 according to an exemplary embodiment of the inventive concept.

Referring to FIGS. 1 and 2, the level shifter 200 includes a voltage selection unit 110 and n voltage level conversion units 150_1, 150_2, . . . , and 150_{—}n, which are connected to the voltage selection unit 110 at the power supply node np. The voltage selected by the voltage selection unit 110 may be applied to the single voltage level conversion unit 150 as illustrated in FIG. 1, or to the n voltage level conversion units 150_1, 150_2, . . . , and 150_{—}n as illustrated in FIG. 2.

The voltage selection unit 110 of FIG. 2 may operate in a similar manner to the voltage selection unit 110 of FIG. 1. Each of the voltage level conversion units 150_1, 150_2, . . . , and 150_{—}n of FIG. 2 may operate in a similar manner to the voltage level conversion unit 150 of FIG. 1.

FIG. 3A is a circuit diagram of an exemplary embodiment of the voltage selection unit 110 illustrated in FIGS. 1 and 2.

Referring to FIG. 3A, the voltage selection unit 110′ may include a first switching unit 310 and a second switching unit 320. The first switching unit 310 may be, for example, a first transistor TR1 having a gate to which the control signal CON is applied, a first terminal connected to a first voltage source for supplying the first voltage V1 to the power supply node np, and a second terminal connected to the power supply node np. The second switching unit 320 may be, for example, a second transistor TR2 having a gate to which an inverted control signal CONB is applied, a first terminal connected to a second voltage source for supplying the second voltage V2 to the power supply node np, and a second terminal connected to the power supply node np. The inverted control signal CONB is obtained by inverting the control signal CON. The first switching unit 310 may apply the first voltage V1 to the power supply node np in response to the control signal CON. The second switching unit 320 may apply the second voltage V2 to the power supply node np in response to the inverted control signal CONB. For example, the control signal CON may have a logic low state during a first time interval and a logic high state during a second time interval. The inverted control signal CONB may have a logic high state during a first time interval and a logic low state during a second time interval. As a result, during the first time interval, the first transistor TR1 is turned on and the second transistor TR2 is turned off, and thus the first voltage V1 is applied to the power supply node np. During the second time interval, the first transistor TR1 is turned off and the second transistor TR2 is turned on, and thus the second voltage V2 is applied to the power supply node np. Therefore, the voltage selection unit 110′ applies either the first voltage V1 or the second voltage V2 to the power supply node np.

FIG. 3B is a circuit diagram of an exemplary embodiment of the voltage selection unit 110 illustrated in FIGS. 1 and 2.

Referring to FIG. 3B, the voltage selection unit 110″ may include a first switching unit 330 and a second switching unit 340. In the exemplary embodiment shown in FIG. 3A, the first and second transistors TR1 and TR2 are p-channel metal-oxide-semiconductor (PMOS) field-effect transistors, and the control signal CON and the inverted control signal CONB are applied to the respective gates of the first and second transistors TR1 and TR2. In the exemplary embodiment shown in FIG. 3B, a transistor TR3 of the first switching unit 330 is implemented using a PMOS transistor, and a transistor TR4 of the second switching unit 340 is implemented using an n-channel metal-oxide-semiconductor (NMOS) field-effect transistor. As a result, the control signal CON is applied to the respective gates of the transistors TR3 and TR4. The voltage selection unit 110″ of FIG. 3B may operate in a similar manner to the voltage selection unit 110′ of FIG. 3A. For example, the voltage selection unit 110″ of FIG. 3B is similar to the voltage selection unit 110′ of FIG. 3A except that the PMOS transistor TR2 in FIG. 3A is replaced with an NMOS transistor TR4 in FIG. 3B, and the inverted control signal CONB applied to the gate of transistor TR2 in FIG. 3A is replaced with control signal CON applied to the gate of transistor TR4 in FIG. 3B.

FIG. 3C is a circuit diagram of an exemplary embodiment of the voltage selection unit 110 illustrated in FIGS. 1 and 2.

Referring to FIG. 3C, the voltage selection unit 110′″ may include a first switching unit 350 and a second switching unit 360. The first switching unit 350 may include a first switch SW1 that may apply the first voltage V1 to the power supply node np in response to the control signal CON. The second switching unit 360 may include a second switch SW2 that may apply the second voltage V2 to the power supply node np in response to the control signal CON. For example, the control signal CON may turn the first switch SW1 on and the second switch SW2 off during a first time interval and turn the first switch SW1 off and the second switch SW2 on during a second time interval. Thus, the voltage selection unit 110′″ applies either the first voltage V1 or the second voltage V2 to the power supply node np.

FIGS. 3A through 3C illustrate exemplary embodiments of the voltage selection unit 110 implementing switches or transistors, however the inventive concept is not limited thereto. The voltage selection unit 110 may be implemented using any components that permit the first voltage V1 to be applied to the power supply node np during a first time interval and the second voltage V2 to be applied to the power supply node np during a second time interval. For example, the voltage selection unit 110 may include, for example, a combination of switches and transistors or a multiplexer for selecting a voltage in response to the control signal CON.

FIG. 4 is a circuit diagram of the voltage level conversion unit 150 illustrated in FIG. 1, according to an exemplary embodiment of the inventive concept.

Referring to FIGS. 1 and 4, the voltage level conversion unit 150 according to an exemplary embodiment of the inventive concept may include a first voltage level control unit 410 and a second voltage level control unit 450.

The first voltage level control unit 410 may establish a connection between the power supply node np and the second node n2, or the third voltage V3 and the second node n2, in response to the input signal IN and a voltage of the first node n1. The first voltage level control unit 410 may include a first transistor PTR1 and a second transistor NTR1. The first transistor PTR1 may include a gate connected to the first node n1, a first terminal connected to the power supply node np, and a second terminal connected to the second node n2. The second transistor NTR1 may include a gate to which the input signal IN is applied, a first terminal connected to the second node n2, and a second terminal to which the third voltage V3 is applied.

If the input signal IN is in a first logic state, the first voltage level control unit 410 may connect the power supply node np to the second node n2 in response to the voltage level at the first node n1. If the input signal IN is in a second logic state, the first voltage level control unit 410 may apply the third voltage V3 to the second node n2. In the exemplary embodiment shown in FIG. 4, the first logic state denotes a logic low state and the second logic state denotes a logic high state. However, the inventive concept is not limited thereto. For example, the voltage level conversion unit 150 may be modified such that the first logic state denotes a logic high state and the second logic state denotes a logic low state.

The second voltage level control unit 450 may establish a connection between the power supply node np and the first node n1, or the third voltage V3 and the first node n1, in response to an inverted input signal INB and the voltage level at the second node n2. The inverted input signal INB is obtained by inverting the input signal IN. The second voltage level control unit 450 may include a third transistor PTR2 and a fourth transistor NTR2. The third transistor PTR2 may include a gate connected to the second node n2, a first terminal connected to the power supply node np, and a second terminal connected to the first node n1. The fourth transistor NTR2 may include a gate to which the inverted input signal INB is applied, a first terminal connected to the first node n1, and a second terminal to which the third voltage V3 is applied.

If the inverted input signal INB is in a first logic state, the second voltage level control unit 450 may connect the power supply node np to the first node n1 in response to the voltage level at the second node n2. If the inverted input signal INB is in a second logic state, the second voltage level control unit 450 may apply the third voltage V3 to the first node n1.

In the exemplary embodiment shown in FIG. 4, the first transistor PTR1 and the third transistor PTR2 are PMOS transistors, and the second transistor NTR1 and the fourth transistor NTR2 are NMOS transistors. However, the inventive concept is not limited thereto.

FIG. 5 is a waveform diagram showing signals input to and output from the voltage level conversion unit 150 illustrated in FIG. 4, as well as signals at each node of the voltage level conversion unit.

An operation of the voltage level conversion unit 150 according to an exemplary embodiment will now be described with reference to FIGS. 1 through 5. In FIG. 5, a first time interval denotes an interval between a point in time t1 and a point in time t3, or an interval between a point in time t4 and a point in time t6. A second time interval denotes an interval between the point in time t3 and the point in time t4. For illustrative purposes, an exemplary embodiment wherein the third voltage V3 is connected to a ground voltage GND, the first voltage V1 is greater than the third voltage V3, and the second voltage V2 is greater than the first voltage V1 will be described. For example, the first voltage V1 may be 3V and the second voltage V2 may be 6V. However, the first, second and third voltages V1, V2 and V3 are not limited thereto.

Before t1, the input signal IN applies a low level voltage, for example, the ground voltage GND, to the first voltage level control unit 410, and the inverted input signal INB applies a high level voltage, for example, the power supply voltage VDD, to the second voltage level control unit 450. As a result, the second transistor NTR1 is turned off and the fourth transistor NTR2 is turned on. Thus, the voltage level at the first node n1 is pulled down to the ground voltage GND, and the first output signal OUT_1 outputs a low level voltage near the ground voltage GND (V3).

Before t1, the control signal CON has the second voltage V2, and the inverted control signal CONB has the ground voltage GND (V3). As a result, the second voltage V2 is applied to the power supply node np. Because the voltage level at the power supply node np is the second voltage V2 and the voltage level at the first node n1 is the ground voltage GND, the first transistor PTR1 is turned on. Accordingly, the voltage level at the second node n2 is pulled up to the second voltage V2, and the second output signal OUT_2 outputs a voltage near the second voltage V2.

At t1, the input signal IN continuously applies the ground voltage GND to the first voltage level control unit 410, and the inverted input signal INB continuously applies the power supply voltage VDD to the second voltage level control unit 450. As a result, the second transistor NTR1 remains off and the fourth transistor NTR2 remains on. Thus, the voltage level at the first node n1 remains at the ground voltage GND (V3), and the first output signal OUT_1 continues to output a low voltage near the ground voltage GND (V3).

At t1, the voltage level of the control signal CON changes from the second voltage V2 to the ground voltage GND (V3), and the voltage level of the inverted control signal CONB changes from the ground voltage GND (V3) to the second voltage V2. As a result, the voltage applied to the power supply node np changes from the second voltage V2 to the first voltage V1. Because the voltage level at the power supply node np is the first voltage V1 and the voltage level at the first node n1 is the ground voltage GND, the first transistor PTR1 is turned on. Accordingly, the voltage level at the second node n2 is pulled down to the first voltage V1, and the second output signal OUT_2 outputs a voltage near the first voltage V1.

At t2, the voltage level of the input signal IN changes from the ground voltage GND to the power supply voltage VDD, and the voltage level of the inverted input signal NB changes from the power supply voltage VDD to the ground voltage GND. As a result, the second transistor NTR1 is turned on and the fourth transistor NTR2 is turned off. Accordingly, the voltage level at the second node n2 is pulled down to the ground voltage GND (V3), and the second output signal OUT_2 outputs a low voltage near the ground voltage GND (V3).

At t2, the voltage level of the control signal CON maintains the ground voltage GND (V3), and the voltage level of the inverted control signal CONB maintains the second voltage V2. As a result, the voltage applied to the power supply node np maintains the first voltage V1. Because the voltage level at the power supply node np is the first voltage V1 and the voltage level at the second node n2 is the ground voltage GND, the third transistor PTR2 is turned on. Accordingly, the voltage level at the first node n1 is pulled up to the first voltage V1, and the first output signal OUT_1 outputs a voltage near the first voltage V1.

At t3 the input signal IN continuously applies the power supply voltage VDD to the first voltage level control unit 410, and the inverted input signal INB continuously applies the ground voltage GND to the second voltage level control unit 450. As a result, the second transistor NTR1 remains on, and the fourth transistor NTR2 remains off. Thus, the voltage level at the second node n2 remains at the ground voltage GND (V3) and the second output signal OUT_2 outputs a voltage near the ground voltage GND (V3).

At t3, the voltage level of the control signal CON changes from the ground voltage GND (V3) to the second voltage V2, and the voltage level of the inverted control signal CONB changes from the second voltage V2 to the ground voltage GND (V3). As a result, the voltage applied to the power supply node np changes from the first voltage V1 to the second voltage V2. Because the voltage level at the power supply node np is the second voltage V2 and the voltage level at the second node n2 is the ground voltage GND, the third transistor PTR2 is turned on. Accordingly, the voltage level at the first node n1 is pulled up to the second voltage V2, and the first output signal OUT_1 outputs a voltage near the second voltage V2.

At t4, the input signal IN continuously applies the power supply voltage VDD to the first voltage level control unit 410, and the inverted input signal INB continuously applies the ground voltage GND to the second voltage level control unit 450. As a result, the second transistor NTR1 remains on and the fourth transistor NTR2 remains off. Thus, the voltage level at the second node n2 remains at the ground voltage GND (V3), and the second output signal OUT_2 outputs a voltage near the ground voltage GND (V3).

At t4, the voltage level of the control signal CON changes from the second voltage V2 to the ground voltage GND (V3), and the voltage level of the inverted control signal CONB changes from the ground voltage GND (V3) to the second voltage V2. As a result, the voltage applied to the power supply node np changes from the second voltage V2 to the first voltage V1. Because the voltage level at the power supply node np is the first voltage V1 and the voltage level at the second node n2 is the ground voltage GND, the third transistor PTR2 is turned on. Accordingly, the voltage level at the first node n1 is pulled down to the first voltage V1, and the first output signal OUT_1 outputs a voltage near the first voltage V1.

At t5, the voltage level of the input signal IN changes from the power supply voltage VDD to the ground voltage GND, and the voltage level of the inverted input signal INB changes from the ground voltage GND to the power supply voltage VDD. As a result, the second transistor NTR1 is turned off and the fourth transistor NTR2 is turned on. Accordingly, the voltage level at the first node n1 is pulled down to the ground voltage GND (V3), and the first output signal OUT_1 outputs a low voltage near the ground voltage GND (V3).

At t5, the voltage level of the control signal CON maintains the ground voltage GND (V3), and the voltage level of the inverted control signal CONB maintains the second voltage V2. As a result, the voltage applied to the power supply node np maintains the first voltage V1. Because the voltage level at the power supply node np is the first voltage V1 and the voltage level at the first node n1 is the ground voltage GND, the first transistor PTR1 is turned on. Accordingly, the voltage level at the second node n2 is pulled up to the first voltage V1, and the second output signal OUT_2 outputs a voltage near the first voltage V1.

At t6, the input signal IN continuously applies the ground voltage GND to the first voltage level control unit 410, and the inverted input signal INB continuously applies the power supply voltage VDD to the second voltage level control unit 450. As a result, the second transistor NTR1 remains off and the fourth transistor NTR2 remains on. Thus, the voltage level at the first node n1 remains at the ground voltage GND (V3) and the first output signal OUT_1 outputs a low level voltage near the ground voltage GND (V3).

At t6, the voltage level of the control signal CON changes from the ground voltage GND (V3) to the second voltage V2, and the voltage level of the inverted control signal CONB changes from the second voltage V2 to the ground voltage GND (V3). As a result, the voltage applied to the power supply node np changes from the first voltage V1 to the second voltage V2. Because the voltage level at the power supply node np is the second voltage V2 and the voltage level at the first node n1 is the ground voltage GND, the first transistor PTR1 is turned on. Accordingly, the voltage level at the second node n2 is pulled up to the second voltage V2, and the second output signal OUT_2 outputs a voltage near the second voltage V2.

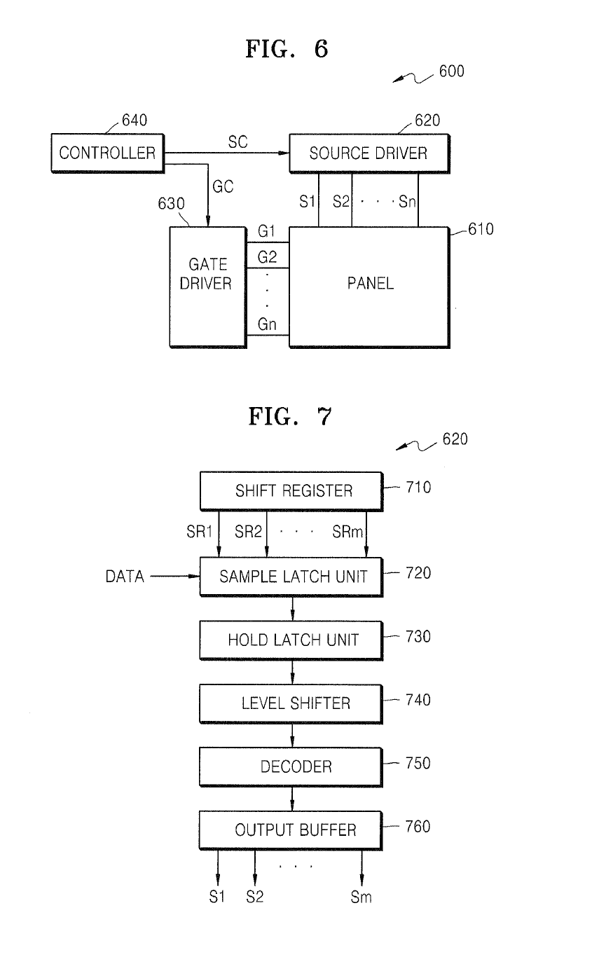

FIG. 6 is a block diagram of a display device 600 according to an exemplary embodiment of the inventive concept.

Referring to FIG. 6, the display device 600 may include a panel 610, a source driver 620, a gate driver 630, and a controller 640. The panel 610 may include a plurality of pixel regions. For example, in the panel 610, a plurality of gate lines G1, G2, . . . , Gn intersect with a plurality of source lines S1, S2, . . . , Sn to form a matrix. The intersections of the gate lines and the source lines define the pixel regions.

The controller 640 may control the source driver 620 and the gate driver 630. The controller 640 receives a plurality of control signals and a plurality of data signals. The controller 640 generates a gate control signal GC and a source control signal SC in response to the received control signals and data signals, and outputs the gate control signal GC to the gate driver 630 and the source control signal SC to the source driver 620.

The gate driver 630 sequentially supplies gate driving signals to the panel 610 through the gate lines G1, G2, . . . , Gn in response to the gate control signal GC. The source driver 620 supplies a predetermined grayscale voltage to the panel 610 through the source lines S1, S2, . . . , Sn in response to the source control signal SC each time the gate lines G1, G2, . . . , Gn are sequentially selected.

FIG. 7 is a block diagram of the source driver 620 according to an exemplary embodiment of the inventive concept.

Referring to FIGS. 1 through 7, the source driver 620 according to an exemplary embodiment may include a shift register 710, a sample latch unit 720, a hold latch unit 730, a level shifter 740, a decoder 750, and an output buffer 760.

The shift register 710 shifts a start pulse signal received from the controller 640. The sample latch unit 720 samples received data DATA in response to output signals SR1, SR2, . . . , SRm output from the shift register 710. The hold latch unit 730 stores the sampled data for a horizontal scan time. The level shifter 740 shifts the voltage level of the data stored in the hold latch unit 730 and outputs the data having the shifted voltage level to the decoder 750. The level shifter 740 may include the level shifter 100 of FIG. 1 or the level shifter 200 of FIG. 2. The operation and structure of the level shifter 740 are similar to the operation and structure of the level shifter 100 or 200 described above with reference to FIGS. 1 through 7. The decoder 750 outputs one of a plurality of grayscale voltages to the output buffer 760 based upon the data having the shifted voltage level received from the level shifter 740. The output buffer 760 outputs the received grayscale voltage to one of a plurality of corresponding source lines S1, S2, . . . , Sm.

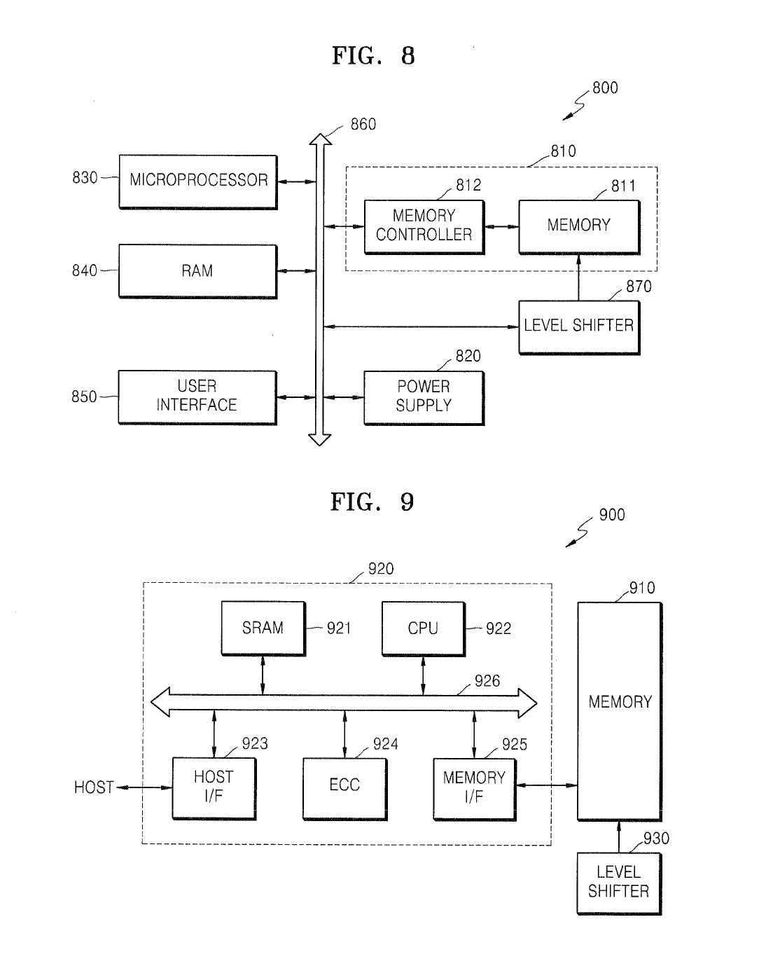

FIG. 8 is a block diagram of a computing system apparatus 800 according to an exemplary embodiment of the inventive concept.

Referring to FIG. 8, the computing system apparatus 800 may include a memory system 810 including a memory controller 812 and a memory device 811, a power supply device 820, and a level shifter 870. The level shifter 870 may include the level shifter 100 or 200 of FIG. 1 or 2. The level shifter 870 may shift the voltage level of a voltage applied to the power supply device 820, and apply the voltage having the shifted voltage level to the memory device 811 and other devices. In the exemplary embodiment shown in FIG. 8, the level shifter 870 and the memory controller 812 are separate devices, however, in another exemplary embodiment, the memory controller 812 may include the level shifter 870.

The computing system apparatus 800 may further include a microprocessor 830, a user interface 850, and a RAM 840 which, along with the memory system 810, the level shifter 870, and the power supply 820, are electrically connected to a bus 860.

In an exemplary embodiment, the computing system apparatus 800 may be a mobile device, and the computing system apparatus 800 may further include a battery for supplying power to the computing system apparatus 800, and a modem, such as, for example, a baseband chipset. The computing system apparatus 800 may further include, but is not limited to, an application chipset, a camera image processor (CIS), and a mobile dynamic random access memory (DRAM).

In an exemplary embodiment, the memory device 811 and the memory controller 812 may include a solid state drive/disk (SSD) that stores data in a non-volatile memory.

FIG. 9 is a block diagram of a memory card 900 according to an exemplary embodiment of the inventive concept.

Referring to FIG. 9, the memory card 900 may include a memory device 910, a memory controller 920, and a level shifter 930. The level shifter 930 may include the level shifter 100 or 200 of FIG. 1 or 2. The level shifter 930 may shift the voltage level of an applied voltage, and apply the applied voltage having the shifted voltage level to the memory device 910 and other devices. In the exemplary embodiment shown in FIG. 9, the level shifter 930 and the memory controller 920 are separate devices, however, in another exemplary embodiment, the memory controller 920 may include the level shifter 930.

The memory controller 920 may communicate with an external host through one of various interface protocols, such as, for example, a universal serial bus (USB), a MultiMediaCard (MMC), a Peripheral Component Interconnect Express (PCI-E), a Serial Advanced Technology Attachment (SATA), a Parallel Advanced Technology Attachment (PATA), a Small Computer System Interface (SCSI), an Enhanced Small Device Interface (ESDI), and an Integrated Drive Electronics (IDE). The construction and operation of a central processing unit (CPU) 922, a synchronous random access memory (SRAM) 921, a host interface (I/F) 923, an ECC 924, a memory I/F 925, and a bus 926 that may be included in an exemplary embodiment of the memory controller 920 would be understood by those of ordinary skill in the art.

The memory devices according to the above exemplary embodiments may be mounted using various packages, such as, for example, a package-on-package (PoP), ball grid arrays (BGAs), chip-scale packages (CSPs), a plastic-leaded chip carrier (PLCC), a plastic dual in-line package (PDIP), a die-in waffle pack, a die-in wafer form, a chip-on board (COB), a ceramic dual in-line package (CERDIP), a plastic metric quad flat pack (MQFP), a thin quad flatpack (TQFP), a small outline integrated circuit (SOIC), a shrink small outline package (SSOP), a thin small outline package (TSOP), a thin quad flatpack (TQFP), a system-in package (SIP), a multi-chip package (MCP), a wafer-level fabricated package (WFP), and a wafer-level processed stack package (WSP).

While the inventive concept has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A level shifter comprising:
a voltage selection unit configured to apply a first voltage to a power supply node during a first time interval and apply a second voltage to the power supply node during a second time interval, in response to a control signal; and
at least one voltage level conversion unit connected to the power supply node and configured to convert a voltage level of an input signal to another voltage level based upon a voltage level at the power supply node and a third voltage.

2. The level shifter of claim 1, wherein the third voltage is a ground voltage, the first voltage has a voltage level greater than the third voltage, and the second voltage has a voltage level greater than the first voltage.

3. The level shifter of claim 1, wherein the voltage selection unit comprises:
a first switching unit configured to connect a first voltage source for providing the first voltage to the power supply node during the first time interval, and to disconnect the first voltage source from the power supply node during the second time interval, in response to the control signal; and
a second switching unit configured to connect a second voltage source for providing the second voltage to the power supply node during the second time interval, and to disconnect the second voltage source from the power supply node during the first time interval, in response to the control signal.

4. The level shifter of claim 3, wherein the first switching unit comprises a p-channel metal-oxide-semiconductor (PMOS) field-effect transistor and the second switching unit comprises an n-channel metal-oxide-semiconductor (NMOS) field-effect transistor.

5. The level shifter of claim 1, wherein the at least one voltage level conversion unit comprises:
a first voltage level control unit configured to apply one of a voltage of the power supply node or the third voltage to a second node, based upon the input signal and a voltage level at a first node; and
a second voltage level control unit configured to apply one of the voltage of the power supply node or the third voltage to the first node, based upon an inverted input signal obtained by inverting the input signal, and a voltage level at the second node,
wherein a first output signal of the at least one voltage level conversion unit is output through the first node, and a second output signal of the at least one voltage level conversion unit is output through the second node.

6. The level shifter of claim 5, wherein the first voltage level control unit is configured to connect the second node to the power supply node while the input signal is in a first logic state, and to connect the second node to the third voltage while the input signal is in a second logic state.

7. The level shifter of claim 5, wherein the first voltage level control unit comprises:
a first transistor comprising a gate connected to the first node, a first terminal connected to the power supply node, and a second terminal connected to the second node; and
a second transistor comprising a gate to which the input signal is applied, a first terminal connected to the second node, and a second terminal to which the third voltage is applied.

8. The level shifter of claim 5, wherein the second voltage level control unit is configured to connect the first node to the power supply node while the inverted input signal is in a first logic state, and to connect the first node to the third voltage while the input signal is in a second logic state.

9. The level shifter of claim 5, wherein the second voltage level control unit comprises:
a first transistor comprising a gate connected to the second node, a first terminal connected to the power supply node, and a second terminal connected to the first node; and
a second transistor comprising a gate to which the inverted input signal is applied, a first terminal connected to the first node, and a second terminal to which the third voltage is applied.

10. The level shifter of claim 1, wherein the input signal is changed from a first logic state to a second logic state or from the second logic state to the first logic state during the first time interval.

11. A display device comprising:
a panel comprising a plurality of pixel regions;
a source driver comprising a level shifter and configured to drive source lines of the panel; and
a controller configured to control the source driver,
wherein the level shifter comprises:
a voltage selection unit configured to apply a first voltage to a power supply node during a first time interval and apply a second voltage to the power supply node during a second time interval, in response to a control signal; and
at least one voltage level conversion unit connected to the power supply node and configured to convert a voltage level of an input signal to another voltage level based upon a voltage level at the power supply node and a third voltage.

12. The display device of claim 11, wherein the third voltage is a ground voltage, the first voltage has a voltage level greater than the third voltage, and the second voltage has a voltage level greater than the first voltage.

13. The display device of claim 11, wherein the voltage selection unit comprises:
a first switching unit configured to connect a first voltage source for providing the first voltage to the power supply node during the first time interval and to disconnect the first voltage source from the power supply node during the second time interval, in response to the control signal; and
a second switching unit configured to connect a second voltage source for providing the second voltage to the power supply node during the second time interval and to disconnect the second voltage source from the power supply node during the first time interval, in response to the control signal.

14. The display device of claim 11, wherein the at least one voltage level conversion unit comprises:
a first voltage level control unit configured to apply one of a voltage of the power supply node or the third voltage to a second node, based upon the input signal and a voltage level at a first node; and
a second voltage level control unit configured to apply one of the voltage of the power supply node or the third voltage to the first node, based upon an inverted input signal obtained by inverting the input signal, and a voltage level at the second node,
wherein a first output signal of the at least one voltage level conversion unit is output through the first node, and a second output signal of the at least one voltage level conversion unit is output through the second node.

15. The display device of claim 14, wherein:
the first voltage level control unit is configured to connect the second node to the power supply node while the input signal is in a first logic state, and to connect the second node to the third voltage while the input signal is in a second logic state; and
the second voltage level control unit is configured to connect the first node to the power supply node while the inverted input signal is in a first logic state, and to connect the first node to the third voltage while the input signal is in a second logic state.

16. A system apparatus comprising:
a level shifter configured to shift a voltage level of an applied voltage and to output a shifted voltage; and
a memory device configured to receive the shifted voltage from the level shifter,
wherein the level shifter comprises:
a voltage selection unit configured to apply a first voltage to a power supply node during a first time interval and apply a second voltage to the power supply node during a second time interval, in response to a control signal; and
at least one voltage level conversion unit connected to the power supply node and configured to convert a voltage level of an input signal to another voltage level based upon a voltage level at the power supply node and a third voltage.

17. The system apparatus of claim 16, wherein the third voltage is a ground voltage, the first voltage has a voltage level greater than the third voltage, and the second voltage has a voltage level greater than the first voltage.

18. The system apparatus of claim 16, wherein the voltage selection unit comprises:
a first switching unit configured to connect a first voltage source for providing the first voltage to the power supply node during the first time interval and to disconnect the first voltage source from the power supply node during the second time interval, in response to the control signal; and
a second switching unit configured to connect a second voltage source for providing the second voltage to the power supply node during the second time interval and to disconnect the second voltage source from the power supply node during the first time interval, in response to the control signal.

19. The system apparatus of claim 16, wherein the at least one voltage level conversion unit comprises:
a first voltage level control unit configured to apply one of a voltage of the power supply node or the third voltage to a second node, based upon the input signal and a voltage level at a first node; and
a second voltage level control unit configured to apply one of the voltage of the power supply node or the third voltage to the first node, based upon an inverted input signal obtained by inverting the input signal, and a voltage of the second node,
wherein a first output signal of the at least one voltage level conversion unit is output through the first node, and a second output signal of the at least one voltage level conversion unit is output through the second node.

20. The system apparatus of claim 19, wherein:
the first voltage level control unit is configured to connect the second node to the power supply node while the input signal is in a first logic state, and to connect the second node to the third voltage while the input signal is in a second logic state; and
the second voltage level control unit is configured to connect the first node to the power supply node while the inverted input signal is in a first logic state, and to connect the first node to the third voltage while the input signal is in a second logic state.
